(19) United States
(12) Patent Application Publication
(10) Pub. No.: US 2007/0263750 A1
(43) Pub. Date: Nov. 15, 2007

(54) Mobile communication device

(75) Inventors: Shih-Chieh Ou, Kaohsiung City (TW); Hung-Rung Chung, Kaohsiung City (TW)

Correspondence Address: RABIN & Berdo, PC, 1101 14TH STREET, NW, SUITE 500, WASHINGTON, DC, 20005, US

(73) Assignee: BenQ Corporation, Taoyuan Shien (TW)

(21) Appl. No.: 11/797,587

(22) Filed: May 4, 2007

(30) Foreign Application Priority Data
May 9, 2006 (TW) 95116425

(51) Int. Cl. H03C 7/00

(52) U.S. Cl. 375/315

(57) ABSTRACT

A mobile communication device including a connector, a judging circuit, a first transmission circuit, a second transmission circuit, a data processing module and an audio processing module is provided. The first end of the connector is for receiving and transmitting a data signal of the data processing module or an audio signal of the data processing module. The second end of the connector is for receiving and transmitting the data signal of the data processing module or the audio signal of the data processing module. The judging circuit is coupled to the first end of a connector and outputs a first indicative signal to determine the type of the plug connected to the connector.

This application claims the benefit of Taiwan application Serial No. 95116425, filed May 9, 2006, the subject matter of which is incorporated herein by reference.

### BACKGROUND OF THE INVENTION

1. Field of the Invention

The invention relates in general to a mobile communication device, and more particularly to a mobile communication device whose socket can be connected to several types of accessories.

2. Description of the Related Art

Conventionally, the mobile phone has a socket for connecting an audio transmission line with microphone and earphone functions. When the socket is connected to an audio transmission line, the user does not need to hold the mobile phone when answering a call. Besides, with the popularity of multi-media application, a mobile phone has several functions, such as camera and MP3, in addition to the basic function of phone call. In order to incorporate the extra functions, the mobile phone has another socket for connecting a data transmission line, such that the mobile phone is able to exchange information with the computer or other information facilities via the data transmission line. When the mobile phone is connected to the computer or other information facilities via the data transmission line, the user can browse global information net or access e-mails connected via mobile network link or exchange the data or pictures of the mobile phone and the computer to make the tablecloth and ringing tone carry more personal flavor.

To summarize, the conventional mobile phone has two different sockets for connecting an audio transmission line and a data transmission line respectively. However, the design of two separate sockets occupies too much space of the mobile phone. As the slimness of mobile phone is highly valued and concerned nowadays, the design of separate sockets is a big challenge to mobile phone designers. Moreover, the audio transmission line and the data transmission line need to have respective plugs to match with the sockets of the mobile phone, not only incurring more cost but causing inconvenience to the user.

### SUMMARY OF THE INVENTION

The invention is directed to a mobile communication device whose socket can be connected to several types of accessories, such that the circuit cost is reduced and the appearance of the mobile phone is further improved.

According to a first aspect of the present invention, a mobile communication device is provided. Examples of the mobile communication device include a mobile phone. The mobile phone includes a connector, a judging circuit, a first transmission circuit and a second transmission circuit. The mobile phone determines the type of the plug connected to the connector according to the level of the voltage outputted by the judging circuit.

Besides, the connector includes a first end, a second end and a third end. The mobile communication device further includes an audio processing module and a data processing module. The first transmission circuit is coupled to the second end, the audio processing module and the data processing module. The second transmission circuit is coupled to the, first end, the audio processing module and the data processing module. The judging circuit is coupled to the first end, and outputs a first indicative signal. The detecting module receives the first indicative signal to select and activate the audio processing module or the data processing module.

The invention will become apparent from the following detailed description of the preferred but non-limiting embodiments. The following description is made with reference to the accompanying drawings.

### BRIEF DESCRIPTION OF THE DRAWINGS

FIG. 1 is a block diagram of a mobile communication device according to a preferred embodiment of the invention;

FIG. 2 is a perspective of a mobile communication device according to a preferred embodiment of the invention;

FIG. 3 is a method flowchart of determining the type of the plug according to a preferred embodiment of the invention;

FIG. 4 is a flowchart of an audio processing procedure according to a preferred embodiment of the invention; and

FIG. 5 is a flowchart of a data processing procedure according to a preferred embodiment of the invention.

### DETAILED DESCRIPTION OF THE INVENTION

The mobile communication device of the invention is capable of correspondingly activating an audio processing module or a data processing module according to whether the accessory connected to the socket of the mobile phone is an audio transmission line or a data transmission line. The audio transmission line is for example a hand-free set.

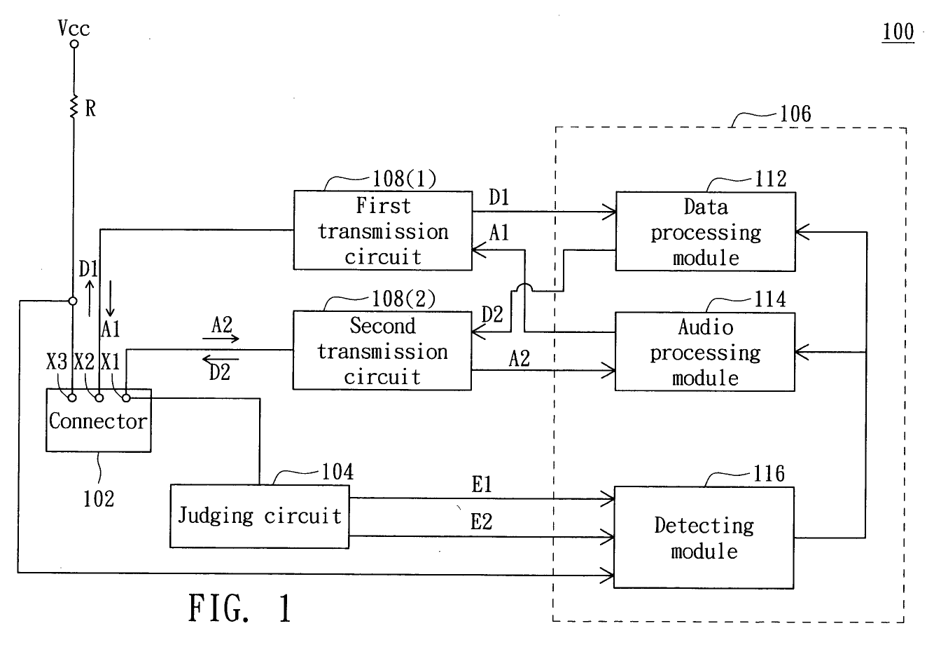

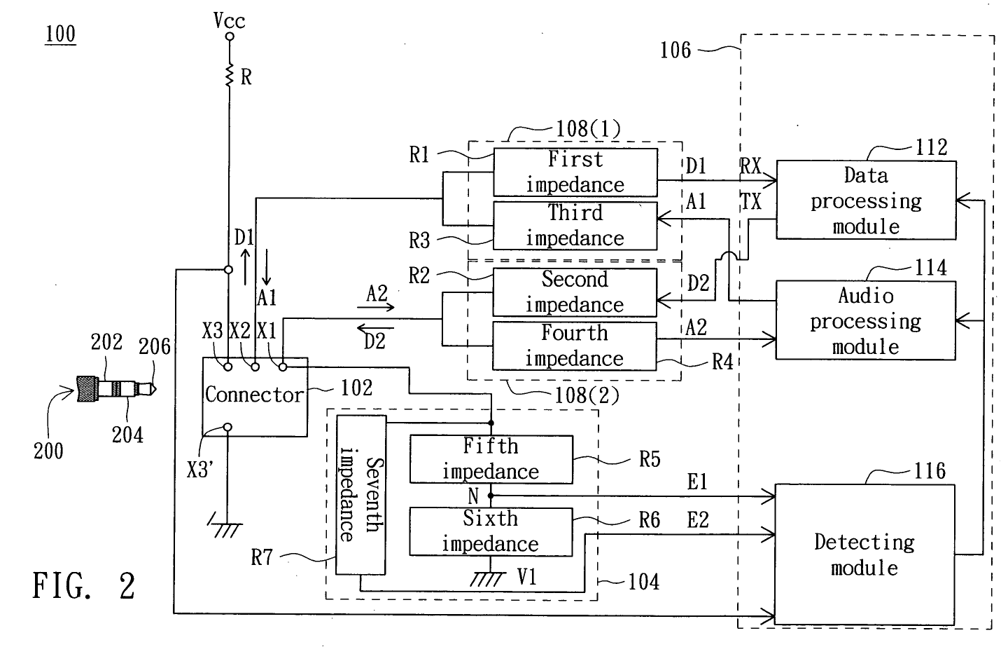

Referring to FIG. 1, a block diagram of a mobile communication device according to a preferred embodiment of the invention is shown. In the present embodiment of the invention, the mobile communication device 100 is exemplified by a mobile phone. The mobile communication device 100 includes a connector 102, a judging circuit 104, a communication host 106, a first transmission circuit 108 (1) and a second transmission circuit 108 (2). The connector 102 is exemplified by a standard 2.5 mm earphone jack selectively connected to the plug of an audio transmission line or a data transmission line (the plug is illustrated in FIG. 2). The mobile communication device 100 receives/transmits an audio or a data signal via the connector 102. For example, the mobile communication device 100 receives/transmits a first audio signal A1 and a second audio signal A2, or receives/transmits a first data signal D1 and a second data signal D2. The connector 102 includes a first end X1, a second end X2 and a third end X3. The first end X1 receives the second audio signal A2 outputted by the audio transmission line, or outputs the second data signal D2 received by the data transmission line. The second end X2 outputs the first audio signal A1 received by the audio transmission line, or receives the first data signal D1 outputted by the data transmission line. The judging circuit 104 is coupled to the first end X1, and outputs a first indicative signal E1 and a second indicative signal E2 according to the voltage level at the first end X1.

The communication host 106 embodying the communication functions of mobile phone further includes a data processing module 112, an audio processing module 114 and a detecting module 116. The data processing module 112 is for processing the first data signal D1 and the second data signal D2. The audio processing module 114 is for processing the first audio signal A1 and the second audio signal A2. The detecting module 116 determines whether the connector 102 is connected to the plug of an audio transmission line or a data transmission line according to the voltage level at the third end X3 of the connector 102. The detecting module 116 also determines whether the connector 102 is connected to the plug of an audio transmission line or a data transmission line according to the voltage level at the first indicative signal E1. The detecting module 116 further determines whether to continue or terminate the audio processing module 114 according to the voltage level at the second indicative signal E2 for the audio processing module 114 to process the audio signals A1 and A2. The first transmission circuit 108 (1) is coupled to the second end X2, the audio processing module 114 and the data processing module 112. The second transmission circuit 108 is coupled to the first end X1, the audio processing module 114 and the data processing module 112.

The mechanism of automatically determining the type of the accessory connected to a socket and further automatically being switched to transmit an audio signal or a data signal is elaborated below. Referring to FIG. 2, a perspective of a mobile communication device according to a preferred embodiment of the invention is shown. The first transmission circuit 108 (1) further includes a first impedance R1 and a third impedance R3. One end of the first impedance R1 is coupled to the second end X2, and the other end of the first impedance R1 is coupled to the data processing module 112. One end of the third impedance R3 is coupled to the second end X2, and the other end of the third impedance R3 is coupled to the audio processing module 114. The second transmission circuit 108 (2) includes a second impedance R2 and a fourth impedance R4. One end of the second impedance R2 is coupled to the first end X1, and the other end of the second impedance R2 is coupled to the data processing module 112. One end of the fourth impedance R4 is coupled to the first end X1, and the other end of the fourth impedance R4 is coupled to the audio processing module. The judging circuit 104 further includes a fifth impedance R5 and a sixth impedance R6. One end of the fifth impedance R5 is coupled to the first end X1. One end of the sixth impedance R6, that is, the node N, is coupled to the other end of the fifth impedance R5, and outputs a first indicative signal E1; the other end of the sixth impedance R6 is coupled to a first fixed voltage V1, such as a ground voltage for example.

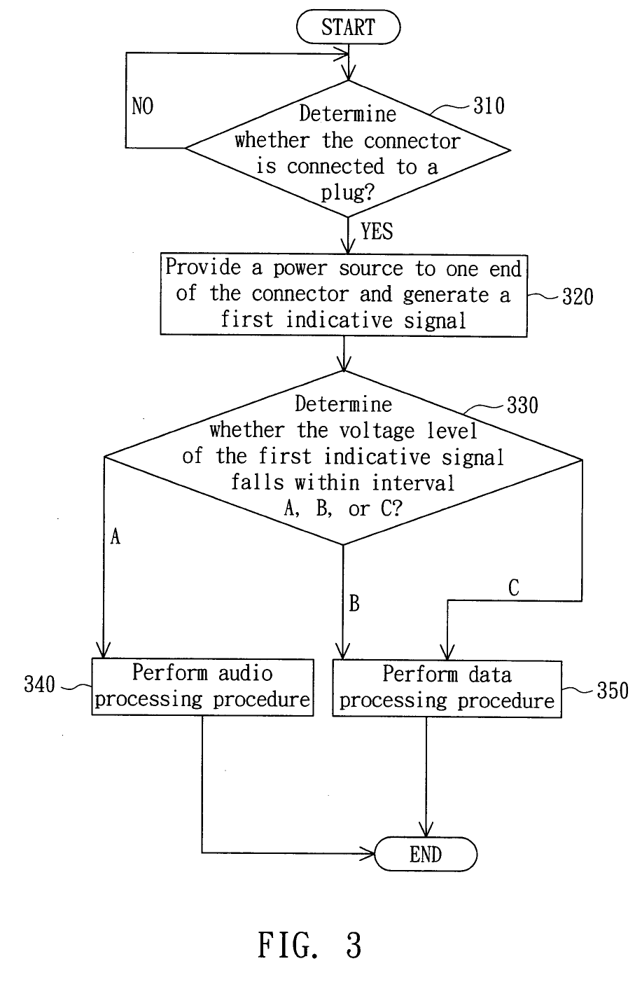

Referring to FIG. 3, a method flowchart of determining the type of the plug according to a preferred embodiment of the invention is shown. Firstly, the method begins at step 310; the detecting module 116 determines whether the connector 102 is connected to a plug 200 according to the voltage level at the third end X3. The plug 200, illustrated in FIG. 2, can be the plug of an audio transmission line or a data transmission line. The plug 200 includes a first signal end 202, a second signal end 204 and a third signal end 206. The first signal end 202 corresponds to the third end X3; the second signal end 204 corresponds to the second end X2; the third signal end 206 corresponds to the first end X1. When the connector 102 is connected to the plug 200, a loop which includes the first signal end 202 the third ends X3 and X3′, a resistance R, and a system power source Vcc is formed. The communication host 106 detects that the voltage level of the third end X3 is decreased a low voltage level from Vcc, thereby the detecting module 116 determines that the connector 102 is connected to the plug 200.

After the detecting module 116 determines that the connector 102 is connected to the plug 200, the method proceeds to step 320, the mobile communication device 100 provides a power source (not illustrated), such as +3V, to the first end X1 and different voltage levels corresponding to the types of the plug 200 will be generated on the node N. After step 320, step 30 is performed to determine whether the voltage level of the first indicative signal falls within interval A, B, or C. For example, if the plug 200 is the plug of the audio transmission line, the voltage of the first indicative signal E1 generated at the node N is between 2.1V and 2.3V (interval A) approximately. If the voltage of the first indicative signal E1 falls within interval A, the detecting module 116 will perform an audio processing procedure as indicated in step 340. If the plug 200 is the plug of the data transmission line and the other end of the data transmission line is not connected to a computer, the voltage of the first indicative signal E1 generated at the node N is between 1.3V and 1.5V (interval B) approximately. If the plug 200 is the plug of the data transmission line and the other end of the data transmission line is connected to a computer, the voltage of the first indicative signal E1 generated at the node N is between 2.4V and 2.6V (interval C) approximately. If the first indicative signal E1 falls within interval B or interval C, the detecting module 116 will perform a data processing procedure as indicated in step 350.

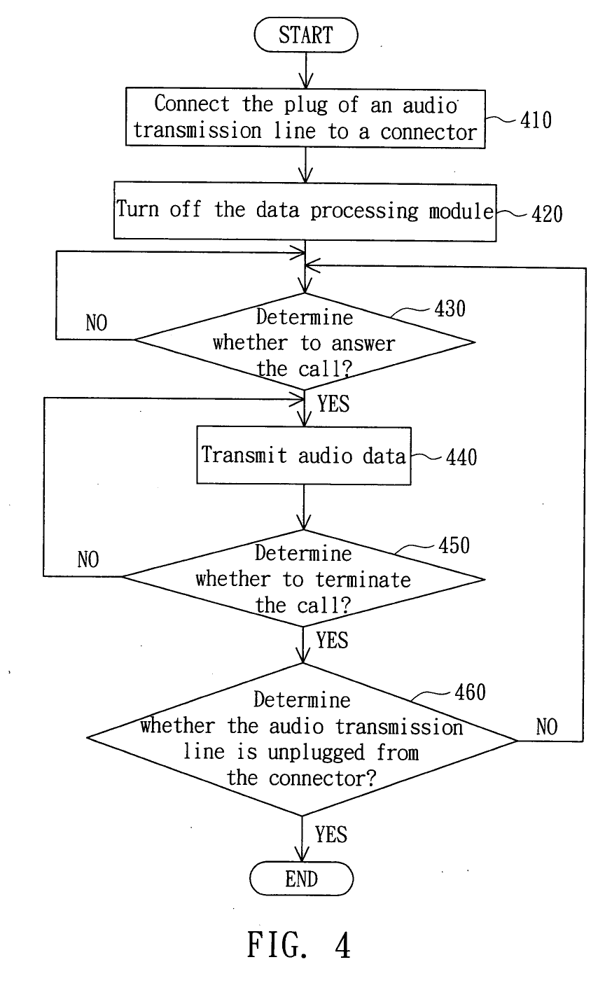

Referring to FIG. 4, a flowchart of an audio processing procedure according to a preferred embodiment of the invention is shown. Firstly, if the voltage level at the first indicative signal E1 is between 2.1V and 2.3V approximately, the connector 102 is connected to the plug of the audio transmission line as indicated in step 410. Next, the procedure proceeds to step 420, the detecting module 116 turns off the data processing module, that is, the voltage level at the transmission end TX and the reception end RX (illustrated in FIG. 2) of the data processing module 112 is set at a low voltage level, lest the communication might be interfered with by noises. The low voltage is the first fixed voltage V1 of the mobile communication device 100. For example, the first fixed voltage V1 is a ground voltage. After that, the procedure proceeds to step 430, the user determines whether to answer the phone call. If yes, the procedure proceeds to step 440, the mobile communication device 100 will enter into a speech mode. For example, the user answers the phone call and activates the audio processing module 114. Thus, the second audio signal A2 is outputted to the first end of the connector X1 from the audio transmission line. Next, the second audio signal A2 is inputted to the audio processing module 114 via the second transmission circuit 108 (2), and the first audio signal A1 is outputted to the first transmission circuit 108 (1) from the audio processing module 114. Afterwards, the first audio signal A1 is outputted to the audio transmission line via the second end of the connector X2. Then, the procedure proceeds to step 450, the user determines whether to terminate the call. After that, the procedure proceeds to step 460, whether the audio transmission line is unplugged from the connector 102 is determined: if no, the procedure returns to step 430 to wait for the next call.

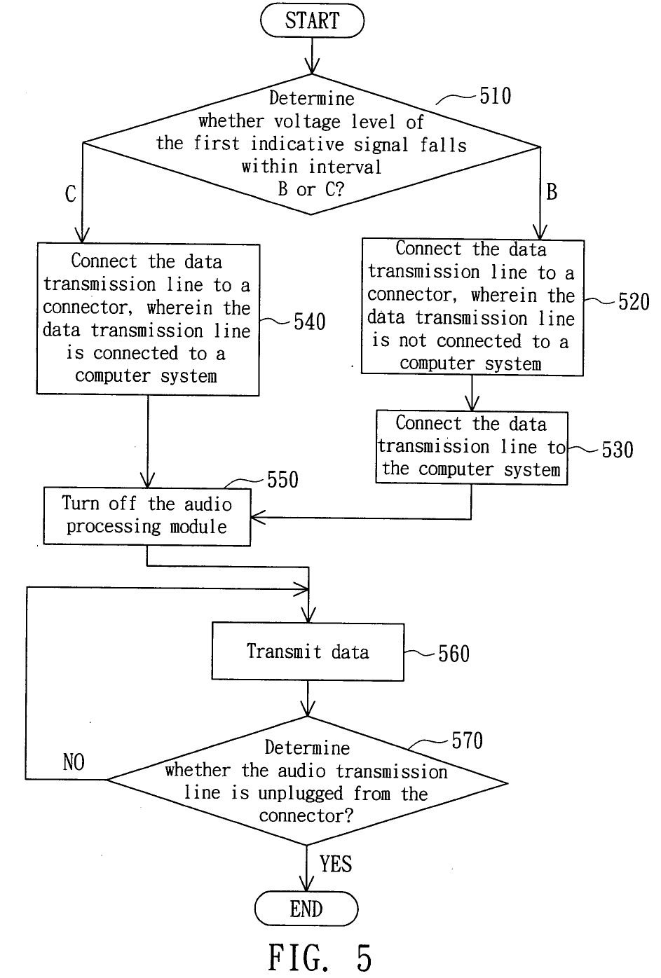

Referring to FIG. 5, a flowchart of a data processing procedure according to a preferred embodiment of the invention is shown. Firstly, the procedure begins at step 510, whether the voltage level at the first indicative signal falls within interval B or interval C is determined. If the voltage level at the first indicative signal E1 is between 1.3V˜1.5V, the connector 102 is connected to the plug of a data transmission line but the data transmission line is not connected to a computer system as indicated in step 520. Next, the procedure proceeds to step 530, the data transmission line is connected to the computer system. If the voltage level at the first indicative signal E1 is between 2.4V˜2.6V, the connector 102 is connected to the plug of the data transmission line which is connected to a computer system as indicated in step 540. Then, the procedure proceeds to step 550, the detecting module 116 will turn off the audio processing module. Meanwhile, the mobile communication device 100 establishes a transmission path of digital data as indicated in step 560. The first digital the data signal D1 is outputted to the second end X2 of the connector from the data transmission line. Next, the first data signal D1 is inputted to the data processing module 112 via the first transmission circuit 108 (1), and the second data signal D2 is outputted to the second transmission circuit 108 (2) from the data processing module 112. Next, the second data signal D2 is outputted to the data transmission line via the first end of the connector X1. After that, the method proceeds to step 570, whether the data transmission line is unplugged from the connector 102 is determined: if no, the procedure returns to step 560 and the transmission of data is continued.

The detecting module of the invention activates the corresponding processing module according to the types of the signals. For example, when the audio signal is transmitted, the detecting module selects and activates the audio processing module; when the data signal is transmitted, the detecting module selects and activates the data signal module. When transmitting a signal, a conventional transmission circuit turns on the power of the data processing module and the audio processing module regardless whether the transmitted signal is a data signal or an audio signal. After the signal type is determined by the detecting module, the transmission path of the signals is switched by a switch. For example, two switches are used to switch the transmission path of the audio signal and the data signal. Compared with the conventional design, switch is not used in the invention, not only saving power consumption and circuit cost but also reducing mobile phone size, further meeting consumers' requirements.

Besides, as indicated in FIG. 2, the judging circuit 104 further includes a seventh impedance R7. One end of the seventh impedance R7 is coupled to one end of the fifth impedance R5, and the other end of the seventh impedance R7 outputs a second indicative signal E2. When the connector 102 is connected to the plug of an audio transmission line, the user can answer or terminate a call by pressing a button disposed on the audio transmission line. If the user presses the button disposed on the audio transmission line, the voltage level of the second indicative signal E2 is changed. On receiving the second indicative signal E2, the detecting module 116 informs the audio processing module 114 to process the first audio signal A1 and the second audio signal A2. Conventionally, the mobile communication device determines whether the user answers or terminates the call according to the voltage level provided by two N-type transistors of an earphone button. The mobile communication device of the invention determines whether the user answers or terminates the call according to the voltage level provided by the second indicative signal E2. Compared with the conventional design of using transistors, the design of the invention not only effectively brings down cost and reduces circuit area and power consumption, but also better meets the requirements expected of a mobile phone.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A mobile communication device used for selectively connecting an audio transmission line or a data transmission line, the mobile communication device comprising:
an audio processing module for receiving and transmitting an audio signal;
a data processing module for receiving and transmitting a data signal;
a connector, comprising a first end and a second end, wherein one of the first end and second end receive the audio signal if the audio signal comes from the audio transmission line while the other of the first end and second end transmit the audio signal if the audio signal is outputted by the audio processing module, and one of the first end and second end receive the data signal if the data signal comes from the data transmission line while the other of the first end and second end transmit the data signal if the data signal is outputted by the data processing module;
a judging circuit coupled to the first end for outputting a first indicative signal; and
a detecting module for receiving the first indicative signal to select and activate the audio processing module or the data processing module.

2. The mobile communication device according to claim 1, further comprising a first transmission circuit and a second transmission circuit, wherein the data signal comprises a first data signal and a second data signal, when the detecting module selects and activates the data processing module, the second end of the connector receives the first data signal, the first data signal is transmitted to the data processing module via the first transmission circuit, and the second data signal is transmitted to the first end of the connector via the second transmission-circuit from the data processing module.

3. The mobile communication device according to claim 2, wherein the first transmission circuit comprises:
a first impedance coupled between the second end of the connector and the data processing module; and
a third impedance coupled between the second end of the connector and the audio processing module;
the second transmission circuit comprises:
a second impedance coupled between the first end of the connector and the data processing module; and
a fourth impedance coupled between the first end of the connector and the audio processing module.

4. The mobile communication device according to claim 1, further comprising a first transmission circuit and a second transmission circuit, wherein the audio signal comprises a first audio signal and a second audio signal, when the detecting module selects and activates the audio processing module, the first end of the connector receives the second audio signal, the second audio signal is transmitted to the audio processing module via the second transmission circuit, the first audio signal is transmitted to the second end of the connector via the first transmission circuit from the audio processing module.

5. The mobile-communication device according to claim 4, wherein the first transmission circuit comprises:
a first impedance coupled between the second end of the connector and the data processing module; and
a third impedance coupled between the second end of the connector and the audio processing module;
the second transmission circuit comprises:
a second impedance coupled between the first end of the connector and the data processing module; and
a fourth impedance coupled between the first end of the connector and the audio processing module.

6. The mobile communication device according to claim 5, wherein the judging circuit further for outputting a second indicative voltage, when the user presses a button of the audio transmission line, the level of the second indicative signal changes to a preset voltage level, the detecting module is used for determining whether to continue or terminate the operation of the audio processing module in response to the second indicative signal.

7. The mobile communication device according to claim 1, wherein the connector further comprises a third end, the third end is adapted to outputting a voltage level to the detecting module, and the detecting module is adapted to detect whether the audio or the data transmission line is connected to the connector according to the voltage level of the third end.

8. A data and audio transmitting method of a mobile communication device, the method comprises:
providing an indicative signal in response to the voltage of a node coupled to a connector which receives an audio transmission line or a data transmission line;
determining whether to activate a data processing module or a audio processing module in response to the indicative signal; and
processing the audio signal by the activated data processing module or processing the data signal by the activated audio processing module.

9. The data and audio transmitting method of mobile communication device according to claim 8, further comprising:
activating the data processing module and processing the data signal transmitted on the data transmission line by the data processing module when one end of the data transmission line is connected to the connector and the other end of the data transmission line is coupled to a computer system.

10. The data and audio transmitting method of mobile communication device according to claim 9, further comprising:
turning off the audio processing module.

11. The data and audio transmitting method of mobile communication device according to claim 8, further comprising:
activating an audio processing module to process an audio signal transmitted on the audio transmission line when the audio transmission line is connected to the connector and the mobile communication device is in a speech mode.

12. The data and audio transmitting method of mobile communication device according to claim 13, further comprising:
turning off the data processing module.

13. The data and audio transmitting method of mobile communication device according to claim 12, further comprising:
setting a reception end and a transmission end of the data processing module to be of a low voltage level.

14. An operating method of a mobile communication device, wherein the mobile communication device comprises a connector, the operating method comprises:
determining whether the connector is connected to a plug;
providing power to one end of the plug and determining whether the plug is the plug of a data transmission line or the plug of a hand-free set according to an indicative voltage level converted from the power when the connector is connected to the plug;
activating a data processing module to process a data signal transmitted on the data transmission line when the connector is connected to the plug of the data transmission line which is coupled to a computer system, wherein the mobile communication device comprises the data processing module;
activating an audio processing module to process an audio signal transmitted on the hand-free set when the connector is connected to the plug of the hand-free set and the mobile communication device is in a speech mode, the mobile communication device comprises the audio processing module.

15. The operating method according to claim 14, wherein the step of activating the data processing module further comprises:
turning off the audio processing module.

16. The operating method according to claim 14, wherein the step of activating the audio processing module further comprises:
setting a reception end and a transmission end of the data processing module to be of a low voltage level.

17. The operating method according to claim 16, wherein the low voltage level is a ground voltage of the mobile communication device.
